(19) United States
(12) Patent Application Publication
(10) Pub. No.: US 2024/0365599 A1
(43) Pub. Date: Oct. 31, 2024

(54) DISPLAY DEVICE AND METHOD OF MANUFACTURING DISPLAY DEVICE

(71) Applicant: Japan Display Inc., Tokyo (JP)

(72) Inventor: Shinichi KAWAMURA, Tokyo (JP)

(73) Assignee: Japan Display Inc., Tokyo (JP)

(21) Appl. No.: 18/623,155

(22) Filed: Apr. 1, 2024

(30) Foreign Application Priority Data
Apr. 28, 2023 (JP) 2023-074508

(51) Int. Cl. H10K 59/122; H10K 59/12; H10K 102/00; H10K 102/10

(52) U.S. Cl. CPC H10K 59/122; H10K 59/1201; H10K 2102/103; H10K 2102/351

(57) ABSTRACT

According to one embodiment, a display device includes a lower electrode, a rib which covers a first portion of the lower electrode and includes a pixel aperture overlapping a second portion of the lower electrode, a partition which includes a bottom portion disposed on the rib, an axis portion disposed on the bottom portion, and a top portion disposed on the axis portion and protruding from a side surface of the axis portion, an organic layer which covers the lower electrode through the pixel aperture and an upper electrode which covers the organic layer and is in contact with the bottom portion. The thickness of the first portion of the lower electrode is different from the thickness of the second portion of the lower electrode.

### CROSS-REFERENCE TO RELATED APPLICATION

This application is based upon and claims the benefit of priority from Japanese Patent Application No. 2023-074508, filed Apr. 28, 2023, the entire contents of which are incorporated herein by reference.

### FIELD

Embodiments described herein relate generally to a display device and a method of manufacturing the display device.

### BACKGROUND

In recent years, display devices in which organic light-emitting diodes (OLEDs) are applied as display elements have been put to practical use.

In the process of manufacturing the display devices, there is a possibility that the display characteristics of the display devices may deteriorate.

### BRIEF DESCRIPTION OF THE DRAWINGS

FIG. 1 is a diagram showing a configuration example of a display device according to an embodiment.

FIG. 2 is a plan view schematically showing an example of layout of subpixels.

FIG. 3 is a cross-sectional view schematically showing the display device taken along line III-III in FIG. 2.

FIG. 4 is a cross-sectional view schematically showing an example of a configuration that can be applied to a partition.

FIG. 5 is a flowchart illustrating an example of a method of manufacturing such a display device.

FIG. 6 is a cross-sectional view schematically showing an example of a process for forming a rib and a partition.

FIG. 7 is a cross-sectional view schematically showing a process following that of FIG. 6.

FIG. 8 is a cross-sectional view schematically showing a process following that of FIG. 7.

FIG. 9 is a cross-sectional view schematically showing a process following that of FIG. 8.

FIG. 10 is a cross-sectional view schematically showing a process following that of FIG. 9.

FIG. 11 is a cross-sectional view schematically showing a process following that of FIG. 10.

FIG. 12 is a cross-sectional view schematically showing an example of a process for forming a display element.

FIG. 13 is a cross-sectional view schematically showing a process following that of FIG. 12.

FIG. 14 is a cross-sectional view schematically showing a process following that of FIG. 13.

FIG. 15 is a cross-sectional view schematically showing a process following that of FIG. 14.

FIG. 16 is a cross-sectional view schematically showing a process following that of FIG. 15.

FIG. 17 is a cross-sectional view schematically showing a process following that of FIG. 16.

FIG. 18 is a diagram illustrating a treatment with a chemical solution.

FIG. 19 is a cross-sectional view schematically showing a resultant including an end portion of an aperture of a pixel after a chemical treatment is performed.

FIG. 20 is a cross-sectional view schematically showing a resultant including an end portion of an aperture of a pixel after the chemical treatment is performed.

FIG. 21 is a flowchart illustrating another example of the method of manufacturing the display device.

### DETAILED DESCRIPTION

In general, according to one embodiment, a display device includes a lower electrode, a rib which covers a first portion of the lower electrode and includes a pixel aperture overlapping a second portion of the lower electrode, a partition which includes a bottom portion disposed on the rib, an axis portion disposed on the bottom portion, and a top portion disposed on the axis portion and protruding from a side surface of the axis portion, an organic layer which covers the lower electrode through the pixel aperture and an upper electrode which covers the organic layer and is in contact with the bottom portion. The thickness of the first portion of the lower electrode is different from the thickness of the second portion of the lower electrode.

Embodiments will be described hereinafter with reference to the accompanying drawings. Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

Note that, in order to make the descriptions more easily understandable, some of the drawings illustrate an X axis, a Y axis and a Z axis orthogonal to each other. A direction along the X axis is referred to as a first direction X, a direction along the Y axis is referred to as a second direction Y, and a direction along the Z axis is referred to as a third direction Z. The third direction Z is a normal direction to a plane containing the first direction X and the second direction Y. Further, viewing the elements parallel to the third direction Z is referred to as plan view.

The display device according to this embodiment is an organic electroluminescent display device including an organic light emitting diode (OLED) as a display element, and can be mounted on various types of electronic devices such as television devices, personal computers, in-vehicle devices, tablet terminals, smartphones, mobile telephone terminals, wearable terminals and the like.

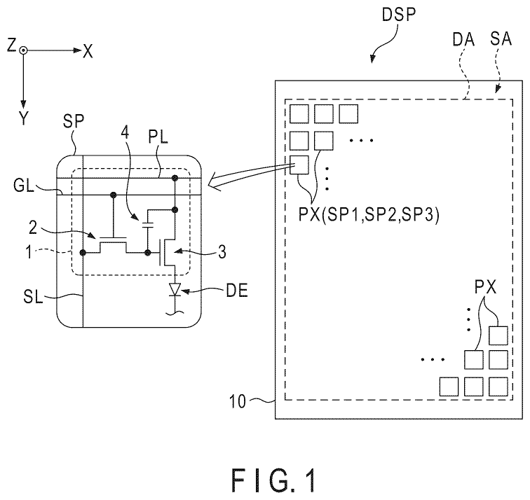

FIG. 1 is a diagram showing a configuration example of a display device DSP according to this embodiment. The display device DSP includes a display area DA on which images are displayed and a peripheral area SA around the display area DA on an insulating substrate 10. The substrate 10 may be of glass or a flexible resin film.

In this embodiment, the shape of the substrate 10 in plan view is rectangular. However, the shape of the substrate 10 in plan view is not limited to rectangular, but may as well be some other shape such as a square, circle, oval or the like.

The display area DA includes a plurality of pixels PX arranged in a matrix along the first direction X and the second direction Y. The pixels PX each include a plurality of subpixels SP. For example, each pixel PX includes a blue subpixel SP1, a green subpixel SP2, and a red subpixel SP3. Note that the pixel PX may as well include a subpixel SP of some other color, such as white, in addition to the subpixels SP1, SP2, and SP3. Further, the pixel PX may as well include a subpixel SP of some other color in place of any of the subpixels SP1, SP2, and SP3.

The subpixels SP each includes a pixel circuit 1 and a display element DE driven by the pixel circuit 1. The pixel circuit 1 includes a pixel switch 2, a drive transistor 3, and a capacitor 4. The pixel switch 2 and the drive transistor 3 are switching elements each constituted by a thin-film transistor, for example.

A gate electrode of the pixel switch 2 is connected to a respective scanning line GL. One of source and drain electrodes of the pixel switch 2 is connected to a respective signal line SL, and the other is connected to the gate electrode of the drive transistor 3 and the capacitor 4. In the drive transistor 3, one of the source electrode and the drain electrode is connected to the power line PL and capacitor 4, and the other is connected to the display element DE.

Note that the configuration of the pixel circuit 1 is not limited to that of the example illustrated in the figure. For example, the pixel circuit 1 may include more thin-film transistors and capacitors.

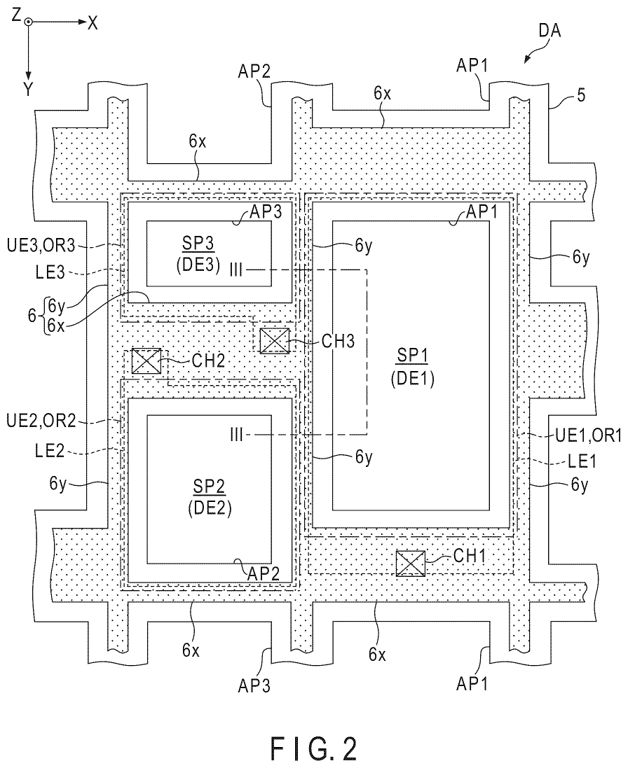

FIG. 2 is a plan view schematically showing an example layout of the subpixels SP1, SP2, and SP3. In the example illustrated in FIG. 2, the subpixels SP2 and SP3 are each aligned with the subpixel SP1 along the first direction X. Further, the subpixel SP2 and the subpixel SP3 are aligned along the second direction Y.

When the subpixels SP1, SP2 and SP3 are laid out as such, rows in each of which a plurality of subpixels SP1 are repeatedly arranged along the second direction Y and rows in each of which subpixels SP2 and SP3 are arranged alternately along the second direction Y are formed in the display area DA. These rows are alternately arranged along the first direction X. Note that the layout of the subpixels SP1, SP2, and SP3 is not limited to that of the example illustrated in FIG. 2.

In the display area DA, a rib 5 and a partition 6 are disposed. The rib 5 includes pixel apertures AP1, AP2, and AP3 in the subpixels SP1, SP2, and SP3, respectively. In the example illustrated in FIG. 2, the pixel aperture AP1 is larger than the pixel aperture AP2, and the pixel aperture AP2 is larger than the pixel aperture AP3.

The partition 6 is disposed at the boundary of each adjacent pair of subpixels SP and overlaps the rib 5 in plan view. The partition 6 includes a plurality of first partitions 6x extending along the first direction X and a plurality of second partitions 6y extending along the second direction Y. The first partitions 6x are each disposed between each respective pair of pixel apertures AP1 adjacent to each other along the second direction Y. The first partitions 6x are each disposed between each respective pair of pixel apertures AP2 and AP3 adjacent to each other along the second direction Y. The second partitions 6y are each disposed between each respective pair of pixel apertures AP1 and AP2 adjacent to each other along the first direction X. Further, the second partitions 6y are each disposed between each pair of pixel apertures AP1 and AP3 adjacent to each other along the first direction X.

In the example illustrated in FIG. 2, the first partitions 6x and the second partitions 6y are connected to each other. With this configuration, the partition 6 as a whole is formed into a grid shape which surrounds the pixel apertures AP1, AP2 and AP3. This can as well be expressed as that the partition 6 includes apertures in the subpixels SP1, SP2 and SP3, respectively, as in the case of the rib 5.

The subpixels SP1 each include a lower electrode LE1, an upper electrode UE1 and an organic layer OR1, which overlap the respective pixel aperture AP1. The subpixels SP2 each include a lower electrode LE2, an upper electrode UE2, and an organic layer OR2, which overlap the respective pixel aperture AP2. The subpixel SP3 has a lower electrode LE3, an upper electrode UE3, and an organic layer OR3, which overlap the respective pixel aperture AP3.

Parts of the lower electrode LE1, the upper electrode UE1 and the organic layer OR1, which overlap the pixel aperture AP1 constitute a display element DE1 of the subpixel SP1. Parts of the lower electrode LE2, the upper electrode UE2, and the organic layer OR2, which overlap the pixel aperture AP2 constitute a display element DE2 of the subpixel SP2. Parts of the lower electrode LE3, the upper electrode UE3 and the organic layer OR3, which overlap the pixel aperture AP3 constitute a display element DE3 of the subpixel SP3. The display elements DE1, DE2 and DE3 may as well further include a cap layer as described below. The rib 5 and the partition 6 surround each of these display elements DE1, DE2 and DE3.

The lower electrode LE1 is connected to the pixel circuit 1 of the subpixel SP1 (see FIG. 1) via a contact hole CH1. The lower electrode LE2 is connected to the pixel circuit 1 of the subpixel SP2 via a contact hole CH2. The lower electrode LE3 is connected to the pixel circuit 1 of the subpixel SP3 via a contact hole CH3. In the example illustrated in FIG. 2, the contact holes CH1, CH2 and CH3 entirely overlap the rib 5 and the partition 6, but the configuration is not limited to that of this example.

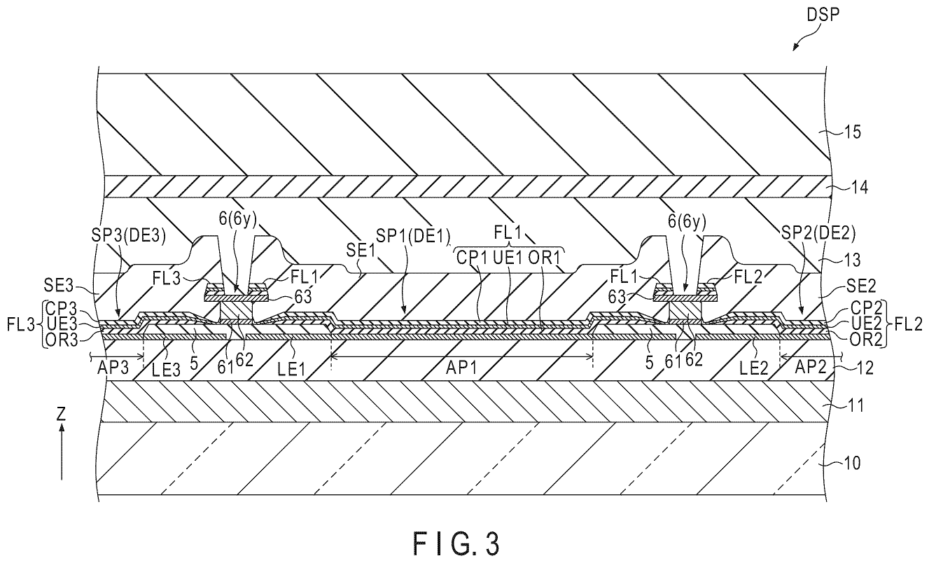

FIG. 3 is a cross-sectional view schematically showing the display device DSP taken along line III-III in FIG. 2. On the substrate 10 described above, a circuit layer 11 is placed. The circuit layer 11 includes various circuits and wiring lines, such as the pixel circuit 1, the scanning lines GL, the signal lines SL, the power line PL and the like, shown in FIG. 1.

The circuit layer 11 is covered by an insulating layer 12. The insulating layer 12 functions as a planarization film that planarizes the unevenness caused by the circuit layer 11. Although not illustrated in the cross section shown in FIG. 3, the contact holes CH1, CH2 and CH3 described above are formed in the insulating layer 12.

The lower electrodes LE1, LE2 and LE3 are disposed on the insulating layer 12. The rib 5 is disposed on the insulating layer 12 and the lower electrodes LE1, LE2 and LE3. End portions of the lower electrodes LE1, LE2 and LE3 are covered by the rib 5.

The partition 6 includes a bottom portion 61 disposed on the rib 5, an axis portion 62 disposed on the bottom portion 61, and a top portion 63 disposed on the axis portion 62. The top portion 63 has a width greater than that of the shaft portion 62. With this configuration, in FIG. 3, both ends of the top portion 63 protrude from side surfaces of the axis portion 62. The shape of the partition 6 having such a configuration is referred to as an overhang shape.

The organic layer OR1 covers the lower electrode LE1 through the pixel aperture AP1. The upper electrode UE1 covers the organic layer OR1 and opposes the lower electrode LE1. The organic layer OR2 covers the lower electrode LE2 through the pixel aperture AP2. The upper electrode UE2 covers the organic layer OR2 and opposes the lower electrode LE2. The organic layer OR3 covers the lower electrode LE3 through the pixel aperture AP3. The upper electrode UE3 covers the organic layer OR3 and opposes the lower electrode LE3.

In the example in FIG. 3, a cap layer CP1 is placed on the upper electrode UE1, a cap layer CP2 is placed on the upper electrode UE2, and a cap layer CP3 is placed on the upper electrode UE3. The cap layers CP1, CP2 and CP3 have a function as optical adjustment layers that improve the efficiency of extraction of light emitted by the organic layers OR1, OR2 and OR3, respectively.

In the following descriptions, a stacked body including the organic layer OR1, the upper electrode UE1, and the cap layer CP1 is referred to as a thin film FL1, a stacked body including the organic layer OR2, the upper electrode UE2, and the cap layer CP2 is referred to as a thin film FL2, and a stacked body including the organic layer OR3, the upper electrode UE3, and the cap layer CP3 is referred to as a thin film FL3.

A part of the thin film FL1 is located above the top portion 63. This part of the thin film FL1 is separated from the portion of the thin film FL1 that is located under the partition 6 (the portion constituting the display element DE1). Similarly, a part of the thin film FL2 is located above the top portion 63, and this part of the thin film FL2 is separated from the portion of the thin film FL2 that is located under the partition 6 (the part constituting the display element DE2). Further, a part of the thin film FL3 is located above the top portion 63 and this part is separated from the portion of the thin film FL3 that is located under the partition 6 (the portion constituting the display element DE3).

In the subpixels SP1, SP2 and SP3, sealing layers SE1, SE2 and SE3 are disposed, respectively. The sealing layer SE1 continuously covers the thin film FL1 and the partition wall around the subpixel SP1. The sealing layer SE2 continuously covers the partition 6 around the thin film FL2 and the subpixel SP2. The sealing layer SE3 continuously covers the partition 6 around the thin film FL3 and the subpixel SP3.

In the example illustrated in FIG. 3, the thin film FL1 and the sealing layer SE1 located on the portion of the partition 6 between the subpixels SP1 and SP2 are separated from the thin film FL2 and the sealing layer SE2 on the partition 6. Further, the thin film FL1 and the sealing layer SE1 located on the portion of the partition 6 between the subpixels SP1 and SP3 are separated from the thin film FL3 and the sealing layer SE3 on the partition 6.

The sealing layers SE1, SE2 and SE3 are covered by a resin layer 13. The resin layer 13 is covered by a sealing layer 14. The sealing layer 14 is covered by a resin layer 15. The resin layers 13 and 15 and the sealing layer 14 are continuously provided at least over the entire display area DA, and a part of the resin layers extend to the peripheral area SA.

A cover member such as a polarizer, a touch panel, a protective film or a cover glass may be further disposed above the resin layer 15. Such a cover member may be adhered to the resin layer 15 via an adhesive layer such as optical clear adhesive (OCA), for example.

The insulating layer 12 is formed of an organic insulating material. The rib 5, the sealing layers 14, SE1, SE2 and SE3 each can be formed of an inorganic insulating material such as silicon nitride (SiN), silicon oxide (SiO), silicon oxynitride (SiON), aluminum oxide (Al₂O₃) or the like. The rib 5, the sealing layer 14, SE1, SE2, and SE3 each may have a single-layer structure of any of the inorganic insulating materials or a stacked body structure in which layers of two or more inorganic insulating materials are stacked one on another. The inorganic insulating materials which form the rib 5, the sealing layer 14, SE1, SE2, and SE3, respectively, may be the same as or different from each other. For example, the rib 5 is formed of silicon oxynitride, whereas the sealing layers 14, SE1, SE2, and SE3 are formed of silicon nitride.

The resin layers 13 and 15 are formed of a resin material (organic insulating material) such as epoxy resin or acrylic resin. The lower electrodes LE1, LE2 and LE3 each include a reflective layer formed of silver (Ag), for example, and a pair of conductive oxide layers which respectively cover the upper and lower surfaces of the reflective layer. Each conductive oxide layer can be formed of a transparent conductive oxide, such as indium tin oxide (ITO), indium zinc oxide (IZO) or indium gallium zinc oxide (IGZO).

The upper electrodes UE1, UE2 and UE3 are formed, for example, of a metallic material such as an alloy of magnesium and silver (MgAg). For example, the lower electrodes LE1, LE2 and LE3 correspond to anodes, and the upper electrodes UE1, UE2 and UE3 correspond to cathodes.

The organic layers OR1, OR2 and OR3 each have a stacked layer structure of, for example, a hole injection layer, a hole transport layer, an electron blocking layer, a light emitting layer, a hole blocking layer, an electron transport layer and an electron injection layer. The organic layers OR1, OR2 and OR3 may have a so-called tandem structure including a plurality of light emitting layers.

The cap layers CP1, CP2 and CP3 are each formed, for example, from a multilayer body of a plurality of transparent thin films. The multilayers may include, as the plurality of thin films, thin films formed of inorganic materials and thin films formed of organic materials. Further, these plurality of thin films have refractive indices different from each other. The materials of the thin films which constitute the multilayer body are different from the materials of the upper electrodes UE1, UE2, and UE3, and also different from the materials of the sealing layers SE1, SE2, and SE3. Note that at least one of the cap layers CP1, CP2 and CP3 may be omitted.

In this embodiment, the bottom portion 61 is formed of, for example, titanium nitride (TiN) or molybdenum-tungsten alloy (MoW). The axis portion 62 can be formed of, for example, aluminum (Al). The axis portion 62 may as well be formed of an aluminum alloy. Usable examples of the aluminum alloy include an aluminum-neodymium alloy (AlNd), an aluminum-yttrium alloy (AlY), and an aluminum-silicon alloy (AlSi). The axis portion 62 may have a single-layer structure of aluminum or aluminum alloy, or it may have a stacked layer structure including a plurality of layers formed of different materials. Further, the axis portion 62 may as well include a layer formed of an insulating material such as silicon nitride, silicon oxide or silicon oxynitride.

The top portion 63 can be formed, for example, of a conductive material such as titanium, titanium nitride, molybdenum, tungsten, molybdenum-tungsten alloy, molybdenum-niobium alloy, ITO or IZO. The top portion 63 may have a single-layer structure of any of these materials or a stacked layer structure including a plurality of layers formed of different materials. Further, the top portion 63 may as well include a layer formed, for example, of an insulating material such as silicon nitride, silicon oxide and silicon oxynitride.

The upper electrodes UE1, UE2 and UE3 are in contact with the bottom portion 61. To the bottom section 61, a common voltage is supplied. This common voltage is supplied to each of the upper electrodes UE1, UE2, and UE3. To the lower electrodes LE1, LE2, and LE3, pixel voltages are respectively supplied through the respective pixel circuits 1 of the subpixels SP1, SP2, and SP3.

The organic layers OR1, OR2 and OR3 emit light in response to the voltage applied. More specifically, when a potential difference is created between the lower electrode LE1 and the upper electrode UE1, the light emitting layer of the organic layer OR1 emits light of the blue wavelength range. When a potential difference is created between the lower electrode LE2 and the upper electrode UE2, the light emitting layer of the organic layer OR2 emits light of the green wavelength range. When a potential difference is created between the lower electrode LE3 and the upper electrode UE3, the light emitting layer of the organic layer OR3 emits light of the red wavelength range.

As another example, the light emitting layers of the organic layers OR1, OR2 and OR3 may emit light of the same color (for example, white). In this case, the display device DSP may include color filters that converts the light emitted by the light emitting layers into light of a color corresponding to each respective one of the subpixels SP1, SP2 and SP3. Further, the display device DSP may as well include a layer containing quantum dots that are excited by the light emitted by the light emitting layers to generate light of colors corresponding to the subpixels SP1, SP2 and SP3, respectively.

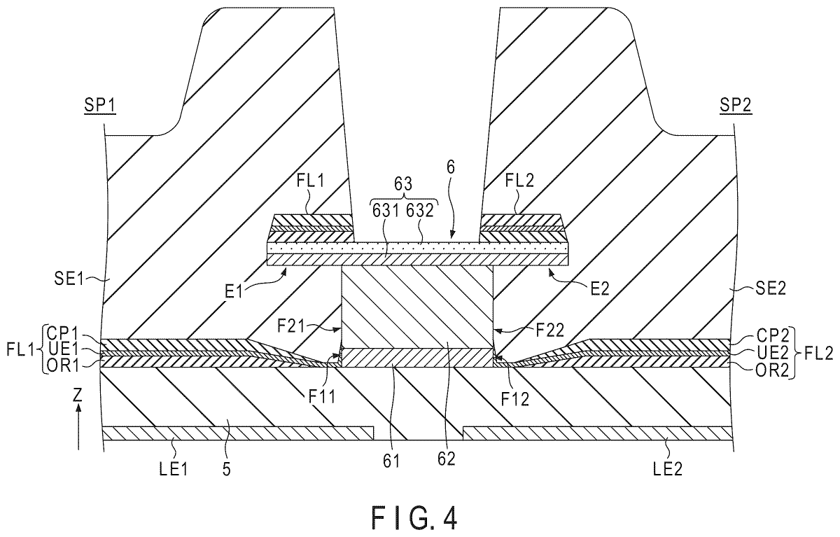

FIG. 4 is a cross-sectional view schematically showing an example of a configuration that may be applied to the partition 6. Here, the portion of the partition wall 6 that is located between the subpixels SP1 and SP2 will be illustrated. A configuration similar to that showing in FIG. 4 can be applied to the portion of the partition 6 located between the subpixels SP1 and SP3 and the portion located between the subpixels SP2 and SP3.

In the example illustrated in FIG. 4, the bottom portion 61 and the axis portion 62 have a single layer structure. The top portion 63 includes a first top layer 631 and a second top layer 632 disposed on the first top layer 631. The materials of the first top layer 631 and the second top layer 632 can be selected from those described above as the materials for the top portion 63. The bottom portion 61 and the top portion 63 are formed thinner than the axis portion 62.

The bottom portion 61 includes a side surface F11 on a side of the subpixel SP1 and a side surface F12 on a side of the subpixel SP2. The axis portion 62 includes a side surface F21 on a side of the subpixel SP1 and a side surface F22 on a side of the subpixel SP2.

In the example illustrated in FIG. 4, the side surfaces F11 and F12 are aligned and form a plane without steps. Similarly, the side surfaces F12 and F22 are aligned and form a plane without steps. In other terms, FIG. 4 shows an example in which the width of the bottom portion 61 and the width of the axis portion 62 are equal to each other.

As another example, the side surface F11 may be slightly set back with respect to the side surface F21. Further, the side surface F11 may protrude with respect to the side surface F21. Similarly, the side surface F12 may be slightly set back with respect to side surface F22. Further, the side surface F12 may protrude with respect to the side surface F22. Although the side surfaces F11, F12, F21, and F22 are parallel to the third direction Z in FIG. 4, the configuration is not limited to that of this example. For example, the side surfaces F11, F12, F21, and F22 may be inclined so that the widths of the bottom portion 61 and the axis portion 62 narrow down as the location approaches the top portion 63.

The top portion 63 protrudes from the side surfaces F21 and F22. More specifically, the top portion 63 has an end portion E1 protruding from the side surface F21 and an end portion E2 protruding from the side surface F22.

The organic layer OR1 is spaced from the side surfaces F11 and F21. The upper electrode UE1 is in contact with at least a part of the side surface F11. In the example illustrated in FIG. 4, the upper electrode UE1 covers the entire side surface F11 and further is brought into contact with a part of the side surface F21. But the configuration is not limited to that of this example, and the upper electrode UE1 may not be in contact with the side surface F21.

Similarly, the organic layer OR2 is spaced from the side surfaces F12 and F22. The upper electrode UE2 is in contact with at least a part of the side surface F12. In the example illustrated in FIG. 4, the upper electrode UE2 covers the entire side surface F12 and further is brought into contact with a part of the side surface F22. But the configuration is not limited to that of this example, and the upper electrode UE2 may not be in contact with the side surface F22.

The sealing layer SE1 covers the thin film FL1 and further covers the portion of the side surface F21 that is not covered by the upper electrode UE1 and the bottom surface of the end portion E1. Similarly, the sealing layer SE2 covers the thin film FL2 and further covers the portion of the side surface F22 that is not covered by the upper electrode UE2 and the bottom surface of the end portion E2.

The configuration of the sealing wall 6 shown in FIG. 4 is only one example. The bottom portion 61 and the axis portion 62 may have a stacked layer structure of two or more layers. Further, the top portion 63 may have a single-layer structure or a stacked layer structure of three or more layers.

Next, a method of manufacturing the display device DSP will now be described using the case where the partition 6 has the structure shown in FIG. 4 as an example. Here, such a case is assumed, for example, that the rib 5 is formed of silicon oxynitride, the bottom portion 61 is formed of titanium nitride, the shaft portion 62 is formed of aluminum, the first top layer 631 is formed of titanium, the second top layer 632 is formed of ITO, and the sealing layers SE1, SE2, and SE3 are formed of silicon nitride.

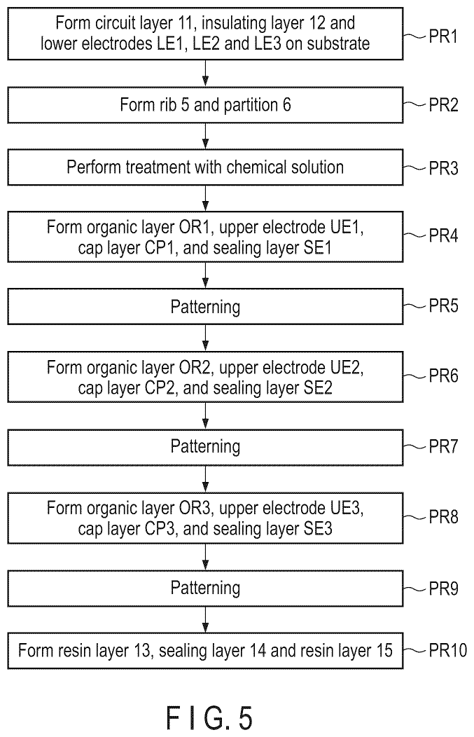

FIG. 5 is a flowchart illustrating an example of the method of manufacturing the display device DSP. In the manufacturing of the display device DSP, first, the circuit layer 11, the insulating layer 12 and the lower electrodes LE1, LE2 and LE3 are formed on the substrate 10 (process PR1). Further, the rib 5 and the partition 6 are formed (process PR2).

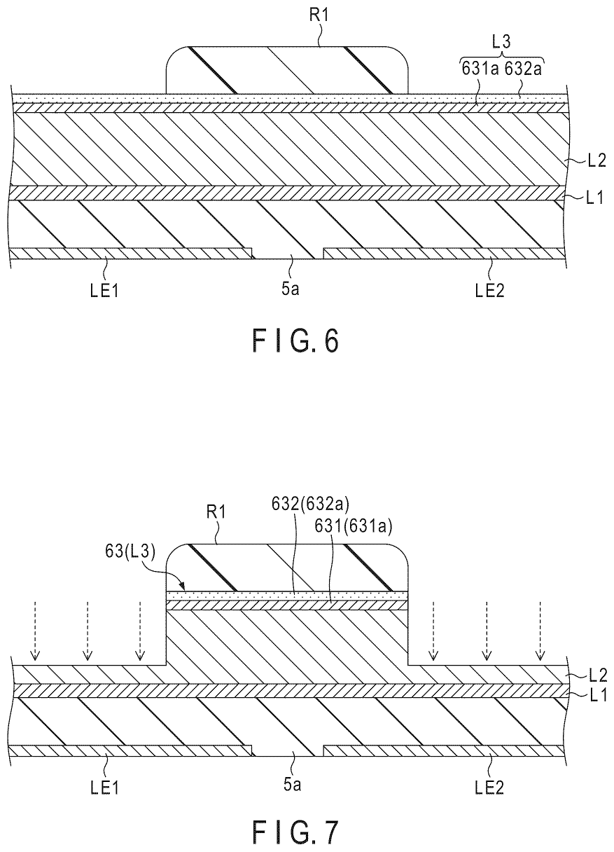

FIGS. 6 to 11 are each a cross-sectional view schematically showing an example of process PR2 for forming the rib 5 and the partition 6. In these figures, the substrate 10, the circuit layer 11 and the insulating layer 12 are omitted.

In process PR2, as shown in FIG. 6, an insulating layer 5a, which is to be processed into the rib 5 is formed, a first layer L1 to processed into the bottom portion 61 is formed on the insulating layer 5a, a second layer L2 to be processed into the axis portion 62 is formed on the first layer L1, a third layer L3 to be processed into the top portion 63 is formed on the second layer L2. Further, a resist R1 patterned in the planar shape of the partition 6 is formed on the third layer L3. The third layer L3 includes a first top layer 631a and a second top layer 632a covering the first top layer 631a.

In this embodiment, the insulating layer 5a is formed of silicon oxynitride, and the thickness of the insulating layer 5a is, for example, 400 nm. The first layer L1 is formed of titanium nitride, and the thickness of the first layer L1 is, for example, 20 nm. The second layer L2 is formed of aluminum, and the thickness of the second layer L2 is, for example, 800 nm. The first top layer 631a is formed of titanium, and the thickness of the first top layer 631a is, for example, 100 nm. The second top layer 632a is formed of ITO, and the thickness of the second top layer 632a is, for example, 50 nm.

Note that the insulating layer 5a is formed by chemical vapor deposition (CVD), for example. Further, the first layer L1, the second layer L2, the first top layer 631a and the second top layer 632a are formed by a sputtering method, for example.

Then, as shown in FIG. 7, the portion of the second top layer 632a exposed from the resist R1 is removed by wet etching. Further, the portion of the first top layer 631a exposed from the resist R1 is removed by anisotropic dry etching. With these etchings, the top portion 63 including the first top layer 631 and the second top layer 632 can be formed.

In the anisotropic dry etching described above, the thickness of the portion of the second layer L2 exposed from the resist R1 and the top portion 63 is also reduced. Note that the configuration is not limited to that of this example, the portion of the second layer L2 exposed from the resist R1 may be removed. Further, the first top layer 631a and the second layer L2 as shown in FIG. 7 may be processed by a different etching process.

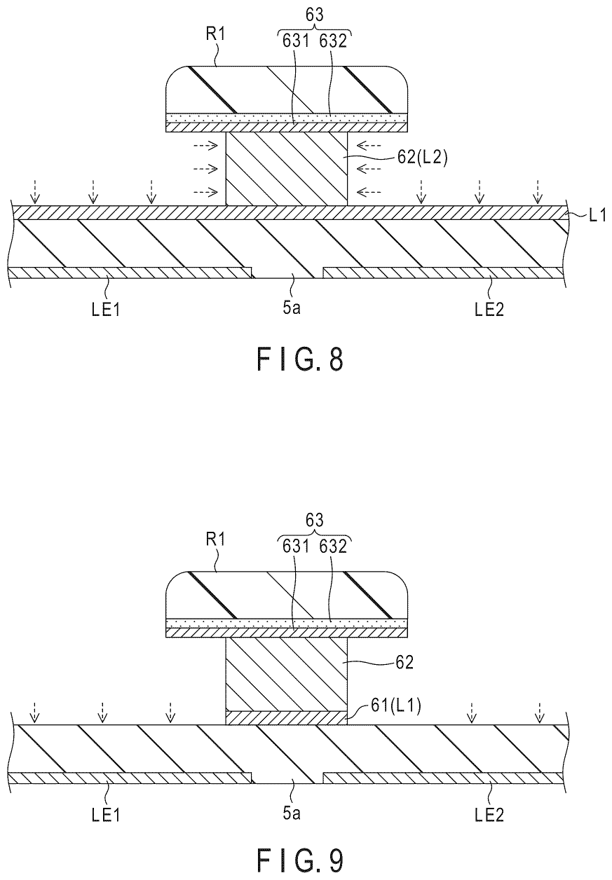

After the process in FIG. 7, the second layer L2 is processed by isotropic wet etching as shown in FIG. 8. In this wet etching, the portion of the second layer L2 whose thickness is reduced in the process of FIG. 7 is removed. Further, the width of the second layer L2 remaining under the top portion 63 is reduced more than the width of the top portion 63. In this manner, the axis portion 62 is formed.

After the process in FIG. 8, as shown in FIG. 9, the portion of the first layer L1 exposed from the axis portion 62 is removed by dry etching. As a result, the bottom portion 61 is formed. After the partition 6 is formed in the processes shown in FIGS. 6 to 9 described so far, the resist R1 is removed.

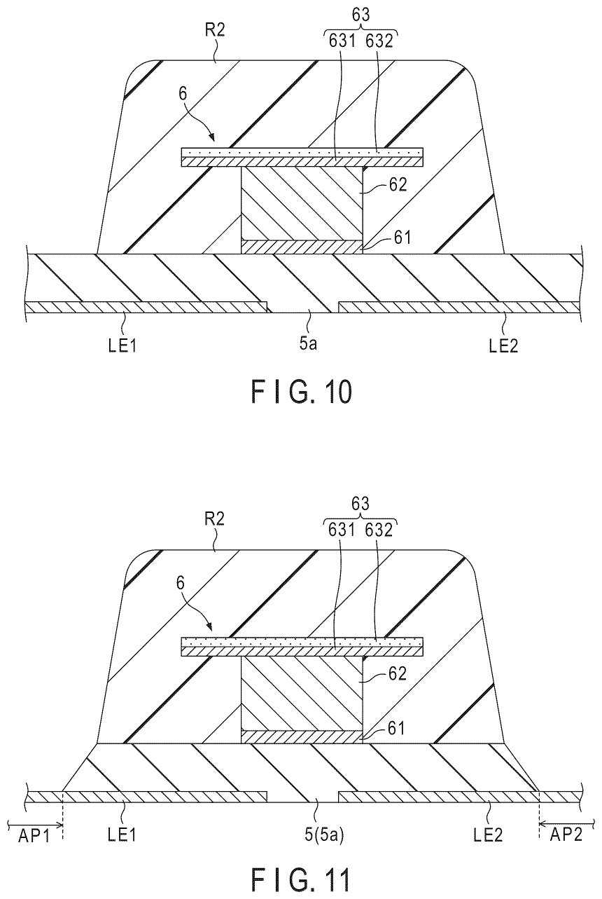

Next, as shown in FIG. 10, a resist R2 patterned into the planar shape of the rib 5 is placed. Further, as shown in FIG. 11, the portion of the insulating layer 5a that is exposed from the resist R2 is removed by dry etching. In this manner, the rib 5 with the pixel apertures AP1, AP2, and AP3 is formed. After this dry etching, the resist R2 is removed.

Note that in the example shown in FIGS. 6 to 11, the explanation is made on the assumption that the pixel apertures AP1, AP2, and AP3 of the rib 5 are formed after the partition 6 is formed. As another example, the partition 6 may be formed after the pixel apertures AP1, AP2, and AP3 of the rib 5 are formed. The processes for processing the first layer L1, the second layer L2, the third layer L3 and the rib 5, that is, for example, wet etching, dry etching and the like, may be modified as appropriate according to the materials used to form these members.

Further, although not shown in the figures, contact holes and the like are formed in the rib 5 located in the peripheral area SA, for example, to supply a common voltage to the bottom section 61 (that is, to connect the bottom section 61 with the backplane).

By the way, when the portion of the insulating layer 5a exposed from the resist R2 is removed by dry etching to form the rib 5 as described above, the surfaces of the lower electrodes LE1, LE2 and LE3, which overlap the pixel apertures AP1, AP2 and AP3, are exposed to dry etching. Therefore, the surfaces of the lower electrodes LE1, LE2, and LE3 may possibly be damaged.

Such damage to the surfaces of the lower electrodes LE1, LE2 and LE3 may affect the surface characteristics of the lower electrodes LE1, LE2, and LE3, which may affect the display characteristics in the display device DSP.

Therefore, in this embodiment, after the process PR2, a treatment with chemical solution is performed to mitigate the effects of the damage on the surfaces of the lower electrodes LE1, LE2, and LE3 described above imparted on the display characteristics in the display device DSP (process PR3). Note that the chemical treatment in process PR3 will be described later.

When the rib 5 and the partition wall 6 are formed and the chemical treatment is carried out as described above, the processes for forming the display elements DE1, DE2, and DE3 are carried out. In this embodiment, such a case is assumed that the display element DE1 is formed, first, the display element DE2 is formed, next, and the display element DE3 is formed last. But, the order in which the display elements DE1, DE2 and DE3 are formed is not limited to that of this example.

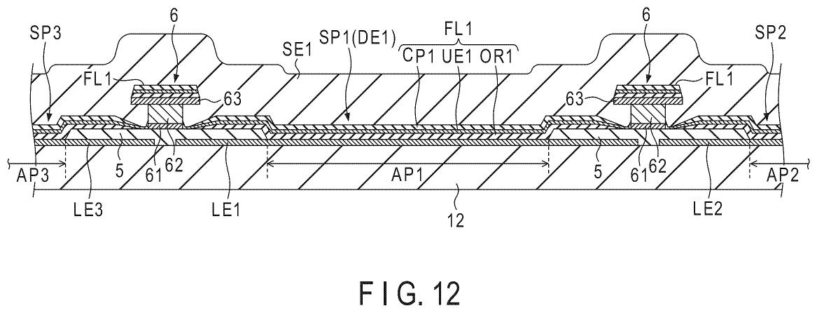

FIGS. 12 to 17 are each a cross-sectional diagram schematically showing another example of the process for forming the display elements DE1, DE2, and DE3. In the formation of the display element DE1, as shown in FIG. 12, first, the organic layer OR1, which covers the lower electrode LE1 through the pixel aperture AP1, the upper electrode UE1, which covers the organic layer OR1 and is in contact with the bottom portion 61, and the cap layer CP1, which covers the upper electrode UE1 are formed in order by vapor deposition, and also the sealing layer SE1, which continuously covers the cap layer CP1 and the partition 6, is formed by CVD (process PR4).

The thin film FL1 including the organic layer OR1, the upper electrode UE1 and the cap layer CP1 is formed at least on the entire display area DA and is disposed over not only the subpixel SP1 but also the subpixels SP2 and SP3 and the partition 6. The thin film FL1 is divided by the overhanging partition 6. The sealing layer SE1 is formed for the entire display area DA and continuously covers the thin film FL1 and the partition 6 without being divided by the partition 6.

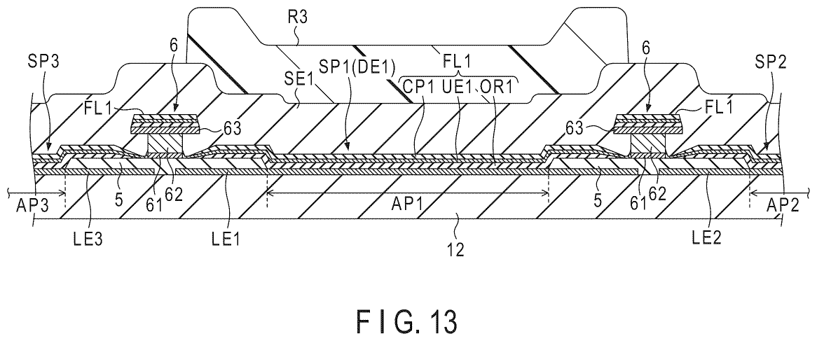

After process PR4, the thin film FL1 and the sealing layer SE1 are patterned (process PR5). In this patterning, a resist R3 is placed on the sealing layer SE1 as shown in FIG. 13. The resist R3 is located above the subpixel SP1 and the portion of the partition 6 located therearound.

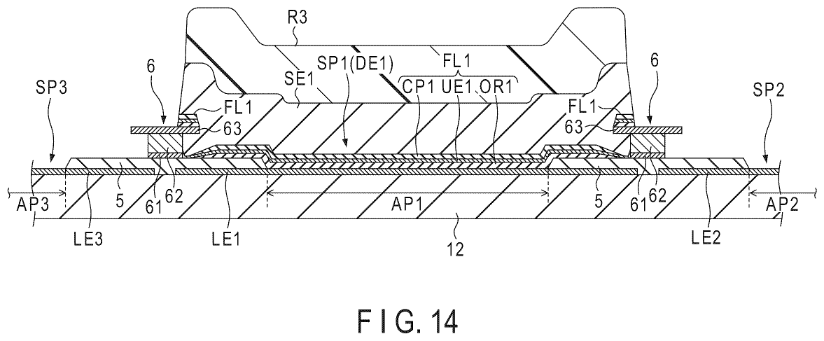

After that, by etching using the resist R3 as a mask, the portion of the thin film FL1 and the sealing layer SE1 exposed from resist R3 is removed as shown in FIG. 14. For example, this etching includes wet etching or dry etching carried out on the sealing layer SE1, the cap layer CP1, the upper electrode UE1, and the organic layer OR1 in order. More specifically, for example, the sealing layer SE1 is removed by dry etching, the cap layer CP1 (multilayer) is removed by wet etching and dry etching, the upper electrode UE1 is removed by wet etching, and the organic layer OR1 is removed by dry etching (for example, ashing).

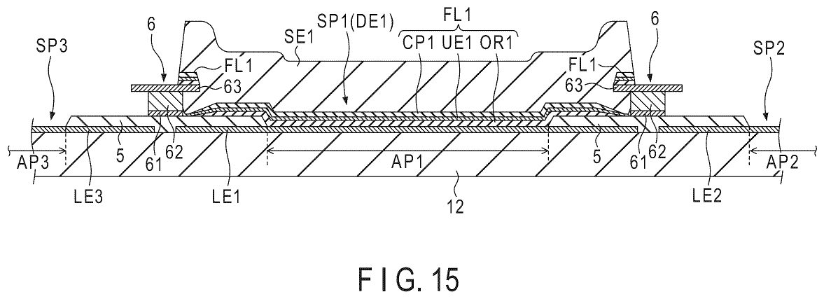

After the process in FIG. 14, the resist R3 is removed. Thus, as shown in FIG. 15, a substrate can be obtained in which the display element DE1 and the sealing layer SE1 are formed in the subpixel SP1 and the display element and the sealing layer are not formed in the subpixels SP2 and SP3.

The display element DE2 is formed by a procedure similar to that of the display element DE1. That is, after process PR5, the organic layer OR2, which covers the lower electrode LE2 through the pixel aperture AP2, the upper electrode UE2, which covers the organic layer OR2, and the cap layer CP2, which covers the upper electrode UE2 are formed in order by vapor deposition, and the sealing layer SE2, which continuously covers the cap layer CP2 and the partition 6 is formed by CVD (process PR6).

The thin film FL2, which includes the organic layer OR2, the upper electrode UE2 and the cap layer CP2 is formed at least for the entire display area DA, and is disposed over not only the subpixel SP2 but also the subpixels SP1 and SP3 and the partition 6. The thin film FL2 is divided by the overhanging partition 6. The sealing layer SE2 is formed for the entire display area DA and continuously covers the thin film FL2 and the partition 6 without being divided by the partition 6.

After process PR6, the thin film FL2 and the sealing layer SE2 are patterned by wet etching or dry etching (process PR7). The flow of this patterning is similar to that of process PR5.

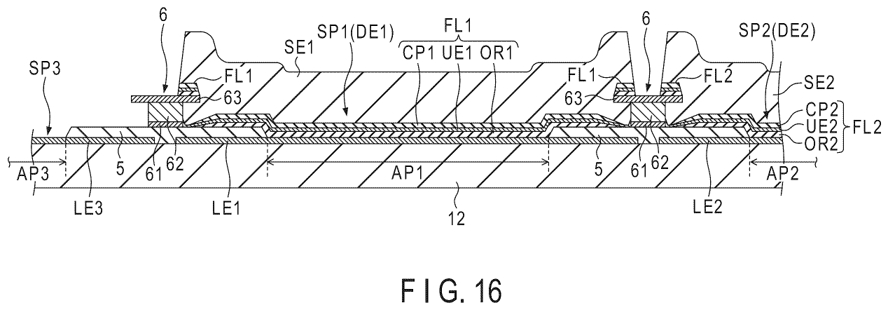

After process PR7, as shown in FIG. 16, such a substrate can be obtained that the display element DE1 and the sealing layer SE1 are formed in the subpixel SP1, the display element DE2 and the sealing layer SE2 are formed in the subpixel SP2, and no display element and sealing layer are formed in the subpixel SP3.

The display element DE3 is formed by a procedure similar to that of the display elements DE1 and DE2. That is, after process PR7, the organic layer OR3, which covers the lower electrode LE3 through the pixel aperture AP3, the upper electrode UE3, which covers the organic layer OR3, and the cap layer CP3, which covers the upper electrode UE3 are formed in order by vapor deposition, and the sealing layer SE3, which continuously covers the cap layer CP3 and the partition 6 is formed by CVD (process PR8).

The thin film FL3, which includes the organic layer OR3, the upper electrode UE3 and the cap layer CP3 is formed at least for the entire display area DA and is disposed over not only the subpixel SP3 but also the subpixels SP1 and SP2 and the partition 6. The thin film FL3 is divided by the overhanging partition 6. The sealing layer SE3 is formed for the entire display area DA and continuously covers the thin film FL3 and the partition 6 without being divided by the partition 6.

After process PR8, the thin film FL3 and the sealing layer SE3 are patterned by wet etching or dry etching (process PR9). The flow of the patterning is similar to that of process PR5.

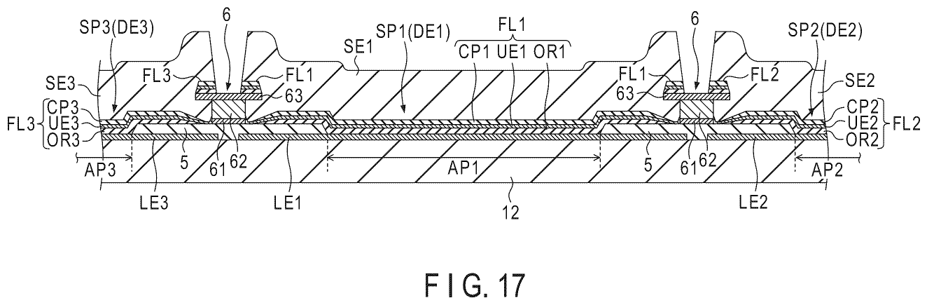

After process PR9, as shown in FIG. 17, such a substrate can be obtained that the display element DE1 and the sealing layer SE1 are formed in the subpixel SP1, the display element DE2 and the sealing layer SE2 are formed in the subpixel SP2, and the display element DE3 and the sealing layer SE3 are formed in the subpixel SP3.

After the display elements DE1, DE2, and DE3 and the sealing layers SE1, SE2, and SE3 are formed, the resin layer 13, the sealing layer 14 and the resin layer 15 shown in FIG. 3 are formed sequentially (process PR10). In this manner, the display device DSP is completed.

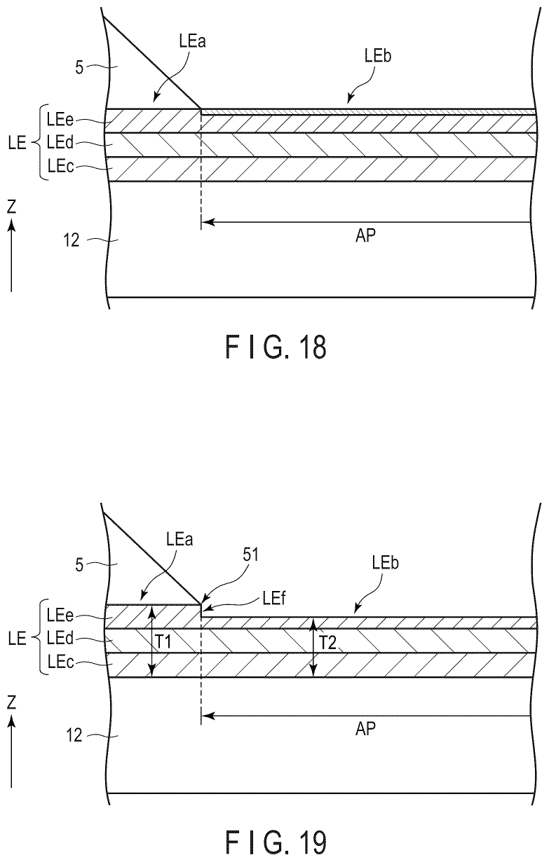

With reference to FIG. 18, the chemical treatment carried out in process PR3 shown in FIG. 5 above will now be described. FIG. 18 is a schematic cross-sectional view including an end portion of the pixel aperture of the rib 5 formed in process PR2 shown in FIG. 5.

Note that the pixel aperture AP shown in FIG. 18 is intended to be one of the pixel apertures AP1, AP2, and AP3 described above. Similarly, the lower electrode LE shown in FIG. 18 is intended to be one of the lower electrodes LE1, LE2, and LE3, which are disposed under the pixel apertures AP.

Further, in the following descriptions, a portion LEa of the lower electrode LE, that is covered by the rib 5 is referred to as a first portion LEa, and a portion LEb of the lower electrode LE, which overlaps the pixel aperture AP1 is referred to as a second portion LEb.

Furthermore, in FIG. 18, only the insulating layer 12, the lower electrode LE and the rib 5 are shown for convenience of explanation.

Here, as shown in FIG. 18, the lower electrode LE has a stacked layer structure including a first conductive oxide layer LEc disposed on the insulating layer 12, a reflective layer LEd disposed on the first conductive oxide layer LEc, and a second conductive oxide layer LEe disposed on the reflective layer LEd.

Note that the first conductive oxide layer LEc is formed of ITO, for example, the reflective layer LEd is formed of silver, for example, and the second conductive oxide layer LEe is formed of ITO, for example.

In this case, the lower electrode LE is prepared by forming a layer constituted by ITO to be processed into the first conductive oxide layer LEc, a layer constituted by silver to be processed into the reflective layer LEd, and a layer constituted by ITO to be processed into the second conductive oxide layer LEe by the sputtering method in order, and then by performing wet etching on these layers on which the resists are formed in order.

The second portion LEb of the lower electrode LE thus formed is exposed in the pixel aperture AP by dry etching to form the rib 5 as described above. But as shown in FIG. 18, the surface of the second conductive oxide layer LEe, which is located on the side where the organic layer OR1 is formed, is damaged by the dry etching.

The display device DSP is manufactured by forming an organic layer on the second conductive oxide layer LEe. Here, if the surface of the second conductive oxide layer LEe is damaged, the display characteristics in the display device DSP may be degraded. More specifically, damage on the surface of the second conductive oxide layer LEe may affect the efficiency of injection of positive holes (holes) in the organic layer which covers the second conductive oxide layer LEe, and may reduce the efficiency of light emission of the organic layer.

For this reason, in this embodiment, the chemical treatment is performed after the rib 5 is formed. Note here that the chemical treatment in this embodiment is performed using a chemical solution that acts on the lower electrode LE (the second conductive oxide layer LEe).

Here, the chemical solution used for the above-described chemical treatment includes, for example, an acidic solution (hereinafter referred to as an acid solution). An example of the acid solution is, for example, a mixture of phosphoric acid, nitric acid, and acetic acid. In the chemical treatment using such an acid solution, the acid solution is brought into contact with the second conductive oxide layer LEe, and thus the acid solution acts on the second conductive oxide layer LEe to remove the surface layer (that is, the damaged layer) of the second conductive oxide layer LEe.

In other words, the chemical solution treatment in this embodiment corresponds to a treatment in which the second portion LEb of the lower electrode LE removes the damaged layer to expose the undamaged layer.

Note that since the chemical treatment (the chemical used in the chemical treatment) may affect, for example, the partition 6 (the bottom portion 61, the axis portion 62 and the top portion 63), the chemical treatment should preferably be carried out in the state where the partition 6 is covered by the resist R2, as shown in FIG. 11, for example.

It should be noted here that the chemical treatment may as well be performed after the resist R2 described above is removed (stripped). More specifically, the chemical treatment carried out after the resist R2 is removed may remove (scrape off), for example, a part of the top portion 63 included in the partition 6. But as compared to the damaged second conductive oxide layer LEe, the degree to which the undamaged top portion 63 is removed by the chemical treatment (thickness) is considered to be small. Further, the top portion 63 has a thickness of about 150 nm. That is, when the chemical treatment has little effect on the top portion 63, such a configuration that the chemical treatment is performed after the resist R2 is removed may be adopted. Furthermore, in the case where the axis portion 62 provided in the partition 6 is formed of aluminum, if the chemical treatment is performed after the resist R2 is removed, oxalic acid, for example, may be used as the chemical solution, which has little effect on the aluminum. Or when using an acid mixture of phosphoric acid, nitric acid and acetic acid as a chemical solution, an acid mixture having a lowered phosphoric acid ratio may be used.

Moreover, although the description here is mainly based on the assumption that the chemical solution used in the chemical treatment is an acid solution, the chemical solution may as well be a solution of alkalinity (hereinafter referred to as “alkaline solution”). In addition, when removing (stripping) the resist R2 shown in FIG. 11 described above, an amine-based alkaline stripping solution may be used. Note that the amine-based alkaline stripping solution may as well be used as a chemical solution in the chemical treatment. According to this, the removal of the resist R2 and the chemical treatment (removal of the surface layer of the second conductive oxide layer LEe) can be carried out at the same time, which may make it possible to achieve manufacturing of the display device DSP even more efficiently.

The chemical solution used for the chemical treatment in this embodiment can be selected as appropriate according to the materials and the like, used to form the lower electrode LE and other components.

Here, FIG. 19 shows a schematic cross-sectional view including the end portion of the pixel aperture AP after the chemical treatment has been performed.

When the chemical treatment is carried out as described above, the surface layer of the second conductive oxide layer LEe, which overlaps the second portion LEb of the lower electrode LE is removed, as shown in FIG. 19. That is, in the display device DSP manufactured by the manufacturing method of this embodiment, the surface of the second conductive oxide layer LEe is scraped off by the chemical treatment, and therefore the thickness T1 of the first portion LEa of the lower electrode LE is different from the thickness T2 of the second portion LEb of the lower electrode, as a configuration.

More specifically, the thickness T1 of the first portion LEa of the lower electrode LE is greater than the thickness T2 of the second portion LEb of the lower electrode LE. In this case, the thicknesses of the first conductive oxide layer LEc and the reflective layer LEd (that is, the layers other than the second conductive oxide layer LEe) are equal to each other for between the first portion LEa of the lower electrode LE and the second portion LEb of the lower electrode LE. But the thickness of the second conductive oxide layer LEe that overlaps the first portion LEa of the lower electrode LE is greater than the thickness of the second conductive oxide layer LEe that overlaps the second portion LEb of the lower electrode LE.

Here, the thickness of the surface layer of the second portion LEb (the second conductive oxide layer LEe) of the lower electrode LE, which is removed by the chemical treatment in this embodiment, is assumed to be about 3 to 5 nm, for example. That is, in the process PR1 shown in FIG. 5 described above, it is preferable that the lower electrode LE having such a thickness that is considered as that the surface layer is removed by the chemical solution treatment (the second conductive oxide layer LEe) should be formed in this way.

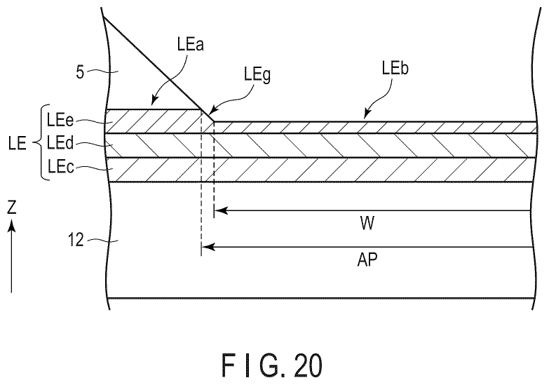

Here, FIG. 19 shows the case where the thickness T1 of the first portion LEa of the lower electrode LE is constant and the thickness T2 of the second portion LEb of the lower electrode LE is constant, that is, the end portion 51 of the rib 5 (the pixel apertures AP) and the end portion LEf of the recess formed in the lower electrode LE (the second conductive oxide layer LEe) by the chemical solution treatment are aligned in plan view. However, the display device DSP of this embodiment may be configured such that the thickness of the part of the second portion LEb of the lower electrode LE, which is close to the rib 5 (the end portion of the respective pixel aperture AP) is greater than the thickness of the portion of the second portion LEb of the lower electrode LE, which is distant away from the rib 5, as shown in FIG. 20, for example. In other words, the recess formed in the lower electrode LE in this embodiment may include an inclined surface LEg. In this case, the display device DSP is configured such that the width W of the thinnest part of the second portion LEb of the lower electrode LE is less than the width of the pixel aperture AP1.

Note here that an organic layer is formed on the lower electrode LE in this embodiment, but it should be assumed that the lower electrode LE (the second conductive oxide layer LEe) in this embodiment is formed into such a shape that at least the organic layer does not enter below the rib 5 in plan view. In this case, for example, such a configuration is sufficient that the thickness of the first portion LEa of the lower electrode LE is constant, or the end portion of the rib 5, which forms the respective pixel aperture AP is in contact with the lower electrode LE (the second conductive oxide layer LEe).

As described above, in this embodiment, the lower electrodes LE (LE1, LE2, and LE3) are formed, the rib 5 including the pixel apertures AP (AP1, AP2, and AP3) which covers the first portion LEa of the lower electrode LE and overlaps the second portion LEb of the lower electrode, and the surface layer of the second portion LEb (the second conductive oxide layer LEe) of the lower electrode LE is removed by using a chemical solution that acts on the second portion LEb. Thus, the display device DSP is manufactured. Note that the display device DSP manufactured as described above has a configuration in which the thickness T1 of the first portion LEa of the lower electrode LE is different from the thickness T2 of the second portion LEb of the lower electrode LE.

Thus, in this embodiment, the effects of damage to the lower electrode LE (the second conductive oxide layer LEe) caused by dry etching to form the rib 5 are mitigated so as to suppress the degradation of display characteristics (decrease in efficiency in light emission in the organic layers OR1, OR2, and OR3) in the display device DSP.

Note that the chemical treatment in this embodiment can be performed using an acid solution or alkali solution as the chemical solution. Further, the chemical treatment in this embodiment may be performed before the resist R2 covering the partition 6 to form the ribs 5 is removed, or it may be performed after the resist R2 is removed.

Further, when using, for example, an amine-based alkaline stripping solution as a chemical solution in this embodiment, the removal (stripping) of the resist R2 and the chemical treatment (removal of the surface layer of the lower electrode LE) may be carried out at the same time.

So far, several methods for manufacturing the display device DSP have been described as described above in this embodiment, but these manufacturing methods for the display device DSP may be combined in any combination. More specifically, for example, after the removal of the resist R2 and the chemical treatment using an amine-based alkaline stripping solution, further chemical treatment may as well be performed using an acid solution. According to such a configuration, it is possible to improve the certainty of suppressing the deterioration of the display characteristics in the display device DSP.

Further, in this embodiment, in consideration of the fact that the surfaces of the lower electrodes LE (LE1, LE2, and LE3) are damaged by dry etching to form the ribs 5, the description is made that the chemical treatment is performed in the process PR3 shown in FIG. 5. But, for example, by the etching performed in the patterning in the process PR5, the surfaces of the lower electrodes LE2 and LE3, which overlap the pixel apertures AP2 and AP3, may be damaged. Furthermore, by the etching performed in the patterning in process PR7 shown in FIG. 5, the surface of the lower electrode LE3 which overlaps the pixel aperture AP3 may be damaged.

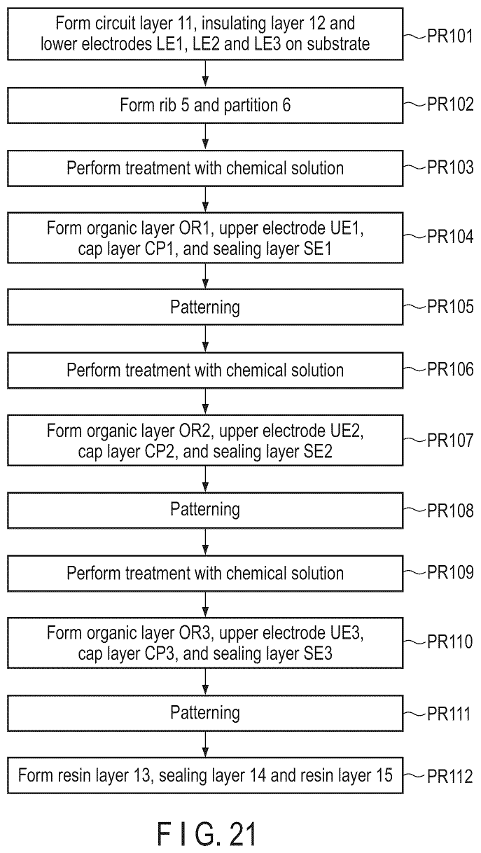

For this reason, the manufacturing method for the display device DSP shown in FIG. 21, for example, may be applied in this embodiment. Although a detailed explanation is omitted, the processes PR101 to PR105, PR107, PR108, and PR110 to PR112 shown in FIG. 21 correspond to the processes PR1 to PR10 shown in FIG. 5. That is, in FIG. 21, the manufacturing method of the display device DSP is shown in which a chemical treatment is further performed in process PR106 after process PR105, which corresponds to process PR5 shown in FIG. 5, and a chemical treatment is further more performed in process PR109 after process PR108, which corresponds to process PR7 shown in FIG. 5.

The chemical treatments carried out multiple times in the manufacturing process of the display device DSP may be of the same treatment or may be different from each other. More specifically, for example, in process PR103 shown in FIG. 21, a chemical treatment using an acid mixture of phosphoric acid, nitric acid, and acetic acid may be performed, and in processes PR106 and PR109, a chemical treatment using an amine-based alkaline stripping solution may be performed. Further, in process PR103, a chemical treatment may be performed before the resist R2 is removed, and in processes PR106 and PR109, a chemical treatment may be performed after the resist R3 is removed.

Moreover, in FIG. 21, chemical treatments are performed multiple times, but such a configuration is sufficient that one or some of the multiple chemical treatments are omitted.

Note that this embodiment may be configured only to remove the surface layer of the lower electrode LE (the second conductive oxide layer LEe) by chemical treatment in order to suppress the degradation of the display characteristics of the display device DSP, and at least part of the manufacturing method of the display device DSP described in this embodiment may be modified.

All display devices and methods of manufacturing a display device, which are implementable with arbitrary changes in design by a person of ordinary skill in the art based on the display devices and methods described above as the embodiments of the present invention, belong to the scope of the present invention as long as they encompass the spirit of the present invention.

Various modifications are easily conceivable within the category of the idea of the present invention by a person of ordinary skill in the art, and these modifications are also considered to belong to the scope of the present invention. For example, additions, deletions or changes in design of the constituent elements or additions, omissions or changes in condition of the processes may be arbitrarily made to the above embodiments by a person of ordinary skill in the art, and these modifications also fall within the scope of the present invention as long as they encompass the spirit of the present invention.

In addition, the other advantages of the aspects described in the above embodiments, which are obvious from the descriptions of the specification or which are arbitrarily conceivable by a person of ordinary skill in the art, are considered to be achievable by the present invention as a matter of course.

What is claimed is:

1. A display device comprising:
a lower electrode;
a rib which covers a first portion of the lower electrode and includes a pixel aperture overlapping a second portion of the lower electrode;
a partition which includes a bottom portion disposed on the rib, an axis portion disposed on the bottom portion, and a top portion disposed on the axis portion and protruding from a side surface of the axis portion;
an organic layer which covers the lower electrode through the pixel aperture; and
an upper electrode which covers the organic layer and is in contact with the bottom portion, wherein
a thickness of the first portion of the lower electrode is different from a thickness of the second portion of the lower electrode.

2. The display device of claim 1, wherein
the thickness of the first portion of the lower electrode is greater than the thickness of the second portion of the lower electrode.

3. The display device of claim 2, wherein
the lower electrode has a stacked layer structure in which a conductive oxide layer is disposed on a side of the organic layer,
a thickness of the conductive oxide layer of the first portion of the lower electrode is greater than a thickness of the conductive oxide layer of the second portion of the lower electrode, and
a thickness of layers other than the conductive oxide layer of the first portion of the lower electrode is equal to a thickness of layers other than the conductive oxide layer of the second portion of the lower electrode.

4. The display device of claim 2 wherein
the thickness of the second portion of the lower electrode is constant.

5. The display device of claim 2, wherein
a thickness of a third portion of the second portion of the lower electrode is greater than a thickness of a fourth portion of the second portion of the lower electrode, the third portion being close to the rib and the fourth portion being distant away from the rib.

6. The display device of claim 5, wherein
a width of a thinnest portion of the second portion of the lower electrode is less than a width of the pixel aperture.

7. The display device of claim 2, wherein
the thickness of the first portion of the lower electrode is constant.

8. The display device of claim 2, wherein
an end portion of the rib, which forms the pixel aperture is in contact with the lower electrode.

9. The display device of claim 1, further comprising:
a cap layer which covers the upper electrode.

10. The display device of claim 9, further comprising:
an sealing layer which continuously covers the cap layer and the partition.

11. A method of manufacturing a display device, comprising:
forming a lower electrode;
forming a rib which covers a first portion of the lower electrode and includes a pixel aperture overlapping a second portion of the lower electrode; and
removing a surface layer of the second portion of the lower electrode using a chemical solution which acts on the lower electrode.

12. The method of claim 11, wherein
the chemical solution is an acidic solution.

13. The method of claim 11, wherein
the chemical solution is an alkaline solution.

14. The method of claim 11, further comprising:
forming a partition which includes a bottom portion, an axis portion located on the bottom portion, and a top portion located on the axis portion and protruding from a side surface of the axis portion, on the rib.

15. The method of claim 14, further comprising:
forming an organic layer which covers the lower electrode through the pixel aperture; and
forming an upper electrode which covers the organic layer and is in contact with the bottom portion.

16. The method of claim 15, further comprising:
forming a cap layer which covers the upper electrode.

17. The method of claim 16, further comprising:
forming a sealing layer which continuously covers the cap layer and the partition.

18. A method of manufacturing a display device, comprising:
forming a lower electrode;
forming a rib which covers a first portion of the lower electrode and includes a pixel aperture overlapping a second portion of the lower electrode; and
reducing a film thickness of the second portion of the lower electrode by using a chemical solution which acts on the lower electrode.

19. The method of claim 18, further comprising:
forming a partition which includes a bottom portion, an axis portion disposed on the bottom portion, and a top portion disposed on the axis portion and protruding from a side surface of the axis portion, on the rib.
